(19) United States
(12) Patent Application Publication
(10) Pub. No.: US 2022/0115836 A1
(43) Pub. Date: Apr. 14, 2022

(54) LIGHT-EMITTING DEVICE, OPTICAL DEVICE, AND INFORMATION PROCESSING DEVICE

(71) Applicant: FUJIFILM BUSINESS INNOVATION CORP., Tokyo (JP)

(72) Inventors: Takeshi MINAMIRU, Ebina-shi (JP); Satoshi Inada, Ebina-shi (JP); Takafumi Higuchi, Ebina-shi (JP); Shigetoshi Nakamura, Ebina-shi (JP); Kenichi Ono, Ebina-shi (JP)

(73) Assignee: FUJIFILM BUSINESS INNOVATION CORP., Tokyo (JP)

(21) Appl. No.: 17/559,293

(22) Filed: Dec. 22, 2021

Related U.S. Application Data
(63) Continuation of application No. PCT/JP2019/048787, filed on Dec. 12, 2019.

(30) Foreign Application Priority Data
Aug. 8, 2019 (JP) 2019-146381

(51) Int. Cl. H01S 5/02255; H01S 5/183; H01S 5/343; G01B 11/24; G01S 17/894; G01S 7/481; G01S 7/4865

(52) U.S. Cl. CPC H01S 5/02255; H01S 5/18344; H01S 5/34313; G01S 7/4865; G01S 17/894; G01S 7/4814; G01B 11/24

(57) ABSTRACT

A light-emitting device includes: a light source including light-emitting elements configured to oscillate in a single transverse mode; and an optical member that is provided on a light-emitting path of the light source and configured to diffuse and emit light emitted by the light source.

### CROSS-REFERENCE TO RELATED APPLICATIONS

This is a continuation of International Application No. PCT/JP2019/048787 filed on Dec. 12, 2019, and claims priority from Japanese Patent Application No. 2019-146381 filed on Aug. 8, 2019.

### BACKGROUND

### Technical Field

The present invention relates to a light-emitting device, an optical device, and an information processing device.

### Related Art

Patent Literature 1 describes an imaging device including a light source, a diffusion plate that includes plural lenses arranged adjacent to each other on a predetermined plane and diffuses light emitted from the light source, and an imaging element that receives light that is diffused by the diffusion plate and reflected on a subject, in which the plural lenses are arranged in such a manner that a pitch of interference fringes in the diffused light is three pixels or less.

Patent Literature 1: JP-A-2018-54769

### SUMMARY

When a three-dimensional shape is measured by a time-of-flight method, in order to emit light to a measurement target, it is required to diffuse light emitted from a light source and irradiate a predetermined range with a predetermined light intensity distribution. At this time, outside the predetermined range, light intensity gradually attenuates as a distance from the predetermined range increases. Light irradiated outside the predetermined range does not contribute to the measurement of the three-dimensional shape, and thus is wasted.

Aspects of non-limiting embodiments of the present disclosure relate to providing a light-emitting device and the like in which an amount of light reaching outside of a predetermined range is reduced as compared with a case of using a light source which uses multiple transverse mode light-emitting elements.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided a light-emitting device including: a light source including plural light-emitting elements configured to oscillate in a single transverse mode; and an optical member that is provided on a light-emitting path of the light source and is configured to diffuse and emit light emitted by the light source.

### BRIEF DESCRIPTION OF DRAWINGS

Exemplary embodiments) of the present invention be described in detail based on the following figures, wherein:

FIG. 1 illustrates an example of an information processing device to which an exemplary embodiment is applied;

FIG. 2 illustrates three-dimensional shape measurement performed by the information processing device.;

FIG. 3A illustrates an example of an irradiation pattern on the irradiated surface;

FIG. 3B illustrates a light intensity distribution along line A-A of FIG. 3A;

FIG. 4 is a block diagram illustrating a configuration of the information processing device;

FIG. 5A illustrates an example of a plan view of an optical device to which the exemplary embodiment is applied;

FIG. 5B is a cross-sectional view of the optical device taken along line VB-VB of FIG. 5A;

FIG. 6 illustrates an example of a plan view of a light source;

FIG. 7 illustrates a cross-sectional structure of a single-mode VCSEL, having a single long resonator structure included in the light source;

FIG. 8 illustrates a cross-sectional structure of a multi-mode VCSEL having a single λ resonator structure included in a light source for comparison;

FIG. 9A schematically illustrates a relationship between a spread angle of light emitted from the single-mode VCSEL having the long resonator structure;

FIG. 9B illustrates a skirt spread in a light intensity distribution in FIG. 9A;

FIG. 10A schematically illustrates a spread angle of light emitted from the multi-mode VCSEL, having the λ resonator structure for comparison;

FIG. 10B illustrates a skirt spread in a light intensity distribution in FIG. 10A; and

FIG. 11 illustrates a relationship between a spread angle of light emitted from a VCSEL, a skirt spread, and light use efficiency.

### DETAILED DESCRIPTION

Hereinafter, an exemplary embodiment of the present invention will be described in detail with reference to the accompanying drawings.

In many cases, an information processing device identifies whether a user who has accessed the information processing device is permitted to access the information processing device, and permits use of the information processing device, namely the own device, only when it is authenticated that the user is a user whose access is permitted. So far, methods of authenticating the user have used a password, a fingerprint, an iris, or the like. Recently, there is a demand for an authentication method having improved security. As this method, authentication is performed based on a three-dimensional image of a face of the user.

Here, an example in which the information processing device is a portable information processing terminal will be described, and the information processing device authenticates a user by recognizing a face that is captured as a three-dimensional image. It should be noted that the information processing device may be applied to an information processing device such as a personal computer (PC), other than the portable information processing terminal.

Further, a configuration, function, method, or the like described in the present exemplary embodiment may also be applied to acquisition of a three-dimensional image of an object in addition to the recognition of the face shape. That is, the present disclosure may also be applied to acquisition of a three-dimensional image in order to measure a three-dimensional shape of a measurement target that is an object other than the face. In addition, a distance to the measurement target (hereinafter, referred to as a measurement distance) does not matter. In the present exemplary embodiment, the face or the object other than the face that is a target of three-dimensional image acquisition may be referred to as an object to be irradiated or an object to be measured.

(Information Processing Device 1)

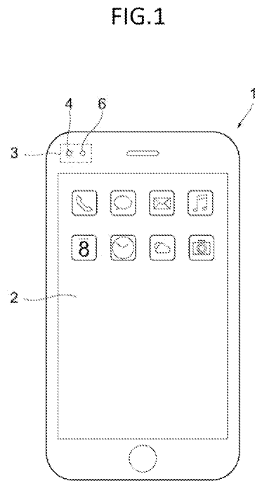

FIG. 1 illustrates an example of an information processing device 1 to which the present exemplary embodiment is applied. As described above, the information processing device 1 is, for example, a portable information processing terminal.

The information processing device 1 includes a user interface unit (hereinafter, referred to as a UI unit) 2, and an optical device 3 that acquires a three-dimensional image. The U1 unit 2 is configured by integrating, for example, a display device that displays information to a user and an input device to which an instruction for information processing is input by an operation of the user. The display device is, for example, a liquid crystal display or an organic EL display. The input device is, for example, a touch panel.

The optical device 3 includes a light-emitting device 4 and a three-dimensional sensor (hereinafter, referred to as a 3D sensor) 6. The light-emitting device 4 emits light toward a measurement target whose three-dimensional shape is to be measured in order to acquire a three-dimensional image, that is, a face in the example described here. The 3D sensor 6 acquires returning light that is emitted from the light-emitting device 4 and reflected by the measurement target, that is, the face in the example described here. Here, the three-dimensional image of the face is acquired based on a so-called time-of-flight (TOF) method based on flight time of light. In the following description, when the measurement target is the face, the face may be referred to as the measurement target.

The information processing device 1 is configured as a computer including a CPU, a ROM, a RAM, and the like. The ROM includes a non-volatile rewritable memory such as a flash memory. Programs and constants stored in the ROM are loaded onto the RAM. When the CPU executes the programs loaded onto the RAM, the information processing device 1 is operated to execute various types of information processing.

(Three-Dimensional Shape Measurement Performed by Information Processing Device 1)

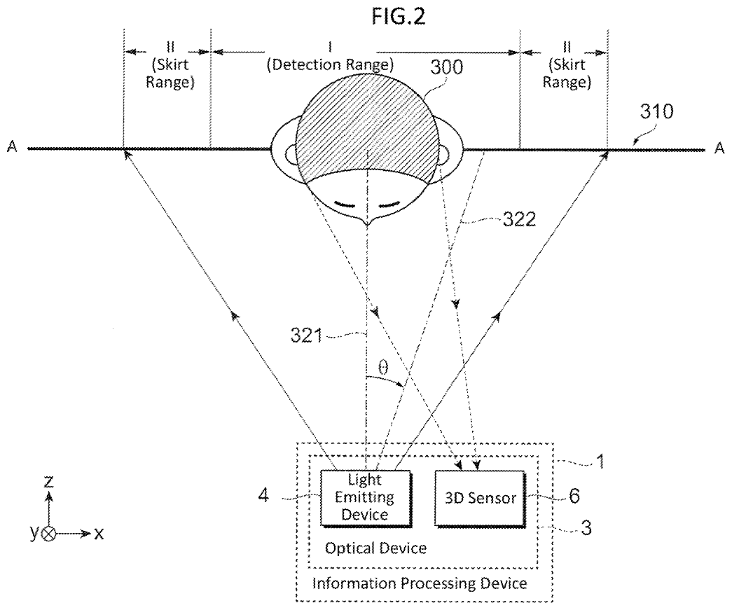

FIG. 2 illustrates three-dimensional shape measurement performed by the information processing device 1. A measurement target here is a face 300. As illustrated in FIG. 2, a right direction in FIG. 2 is defined as an x direction, an upper direction in FIG. 2 is defined as a z direction, and a back side direction perpendicular to a plane of FIG. 2 is defined as a y direction. FIG. 2 is a diagram in which a head including a face is viewed from overhead.

In the optical device 3 of the information processing device 1, light is emitted from the light-emitting device 4 toward the face 300. Then, the 3D sensor 6 receives the light reflected by the face 300. That is, the optical device 3 is configured such that light is emitted from the light-emitting device 4 toward the measurement target and the reflected light from the measurement target is received by the 3D sensor 6. At this time, the light-emitting device 4 emits light toward an irradiated surface 310 that is a virtual surface provided to face the light-emitting device 4. Here, the light-emitting device 4 and the irradiated surface 310 face each other. The light-emitting device 4 is located on a perpendicular line 321 to the irradiated surface 310. The perpendicular line 321 is drawn to a center of a detection range I to be described later. Line A-A passes through the center of the detection range I (intersection with the perpendicular line 321) and traverses on the irradiated surface 310 in the x direction. A line connecting the light-emitting device 4 and an arbitrary point on line A-A is defined as a line 322. An angle θ is an angle between the perpendicular line 321 and the line 122.

A detection range I, in which the face 300 is detected and a three-dimensional shape of the face 300 is measured, and a skirt range II surrounding the detection range I are formed on the irradiated surface 310. The detection range I is a range irradiated with light having light intensity that enables the three-dimensional shape of the face 300 to be measured by reflected light when the face 300 is present in this region. Meanwhile, the skirt range II is a range in which light intensity decreases as a distance from the detection range I increases. Therefore, even when the face 300 is present in the skirt range II, the three-dimensional shape of the face 300 is not measured with high accuracy as compared with the case where the face 300 is present in the detection range I. That is, the skirt range II is a non-detection range that is not suitable for measuring the three-dimensional shape of the face 300. The detection range I and the skirt range II are ranges where the light from the light-emitting device 4 is irradiated. The detection range I is a predetermined range for measuring the three-dimensional shape, and is a range irradiated with light with a predetermined light intensity distribution. Here, the light intensity refers to luminous intensity.

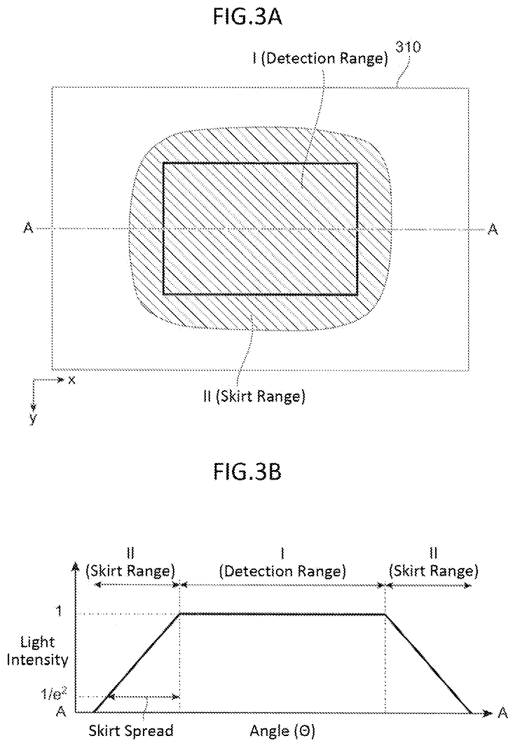

FIGS. 3A and 3B illustrate the irradiated surface 310. FIG. 3A illustrates an example of an irradiation pattern on the irradiated surface 310, and FIG. 3B illustrates a light intensity distribution along line A-A of FIG. 3A. A shape irradiated with the light on the irradiated surface 310, that is, a shape of a portion where the light is irradiated, is referred to as the irradiation pattern. In FIG. 3B, a horizontal axis represents the angle θ between the perpendicular line 321 and the line 322 illustrated in FIG. 2, and a vertical axis represents light intensity on the irradiated surface 310.

It is assumed that the irradiation pattern illustrated in FIG. 3A has a quadrangular shape whose longitudinal direction is oriented in the x direction and whose corners are rounded. In this irradiation pattern, a rectangular range surrounded by a solid line in a central portion is set as the detection range I, and a peripheral portion of the detection range I is set as the skirt range II. The skirt range 11 is formed outside the detection range I so as to surround the detection range I. The detection range I may be set to have a shape other than the rectangular shape.

The detection range I is set to have a predetermined light intensity distribution. Although it is assumed that light intensity of the detection range 1 is constant in FIG. 3B, the distribution may also vary within a predetermined allowable range. That is, as long as the light intensity enables measurement of a three-dimensional shape of the object to be irradiated, the distribution may vary in the region of the detection range I. For example, in the detection range 1, light intensity of a center side may be weaker than light intensity of a peripheral side, or the light intensity of the center side may be stronger than the light intensity of the peripheral side. Meanwhile, in the skirt range II, the light intensity gradually decreases from the light intensity of the detection range I as the distance from the detection range I increases. Here, an angle difference from an angle of a boundary between the detection range I and the skirt range II to an angle at which the light intensity becomes 1/e² of a maximum value in the skirt range II is defined as a skirt spread. The skirt spread indicates a size of the skirt range II. As described above, the skirt range II is unsuitable for measuring the three-dimensional shape of the face 300, and may be located out of the detection range used for the three-dimensional shape measurement. In this case, the light irradiated to the skirt range 11 is ineffective. Therefore, use efficiency of the light emitted from the light-emitting device 4 (hereinafter, referred to as light use efficiency) is increased as an area of the skirt range II becomes smaller, that is, as the skirt spread becomes smaller. The light use efficiency refers to a ratio of an amount of light emitted into the detection range I to an amount of light emitted by the light-emitting device 4. The light irradiated to the skirt range II may be referred to as skirt light. The skirt spread may be evaluated by full width at half maximum (FWHM) of the light intensity. In addition, the skirt spread may be evaluated by an index other than the angle, for example, a width of the skirt range II on the irradiated surface 310 that is placed at a predetermined distance from the light-emitting device 4.

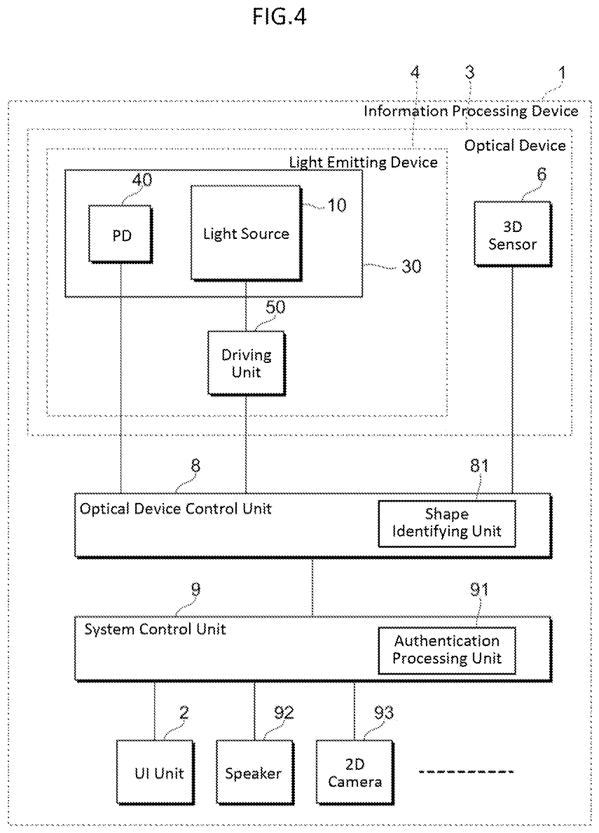

FIG. 4 is a block diagram illustrating a configuration of the information processing device 1.

The information processing device 1 includes the optical device 3 described above, an optical device control unit 8, and a system control unit 9. As described above, the optical device 3 includes the light-emitting device 4 and the 3D sensor 6. The optical device control unit 8 controls the optical device 3. The optical device control unit 8 includes a shape identifying unit 81, The system control unit 9 controls the entire information processing device 1 as a system. The system control unit 9 includes an authentication processing unit 91. The UI unit 2, a speaker 92, and a two-dimensional camera (denoted as a 2D camera in FIG. 4) 93, and the like are connected to the system control unit 9. The 3D sensor 6 is an example of a light-receiving unit.

Hereinafter, the components described above will be described in order.

The light-emitting device 4 included in the optical device 3 includes a light source 10, a diffusion plate 30, a light-receiving element 40 (denoted as PD in FIG. 41 for monitoring light amount and a driving unit 50. The light source 10, the diffusion plate 30, and the light-receiving element 40 for monitoring light amount in the light-emitting device 4 will be described later. The diffusion plate 30 is an example of an optical member.

The driving unit 50 in the light-emitting device 4 drives the light source 10. For example, the light source 10 is driven by the driving unit 50 so as to repeat emitting pulsed light at several tens of MHz to several hundreds of MHz. The light emitted by the light source 10 is referred to as emitted light, and pulsed light emitted from the light source 10 is referred to as emitted light pulse.

The 3D sensor 6 includes plural light-receiving regions arranged in a lattice pattern. The 3D sensor 6 receives pulsed light reflected from the measurement target in response to the emitted light pulse from the light source 10 of the light-emitting device 4. The light pulse received by the 3D sensor 6 is referred to as a received light pulse. Then, the 3D sensor 6 outputs, as a digital value for each light-receiving region, a signal corresponding to a time from when the light is emitted from the light source 10 to when the light reflected by the measurement target is received by the 3D sensor 6. For example, the 3D sensor 6 is configured as a device having a CMOS structure in which each light-receiving region includes two gates and two charge accumulating units corresponding to the gates. The 3D sensor 6 is configured to alternately transfer photoelectrons generated in each light-receiving region to one of the two charge accumulating units by alternately applying pulses to the two gates, and to accumulate charges corresponding to a phase. difference between the emitted light pulse and the received light pulse. Then, the digital value corresponding to the charges corresponding to the phase difference between the emitted light pulse and the received light pulse is output for each light-receiving region as a signal via an AD converter.

The 3D sensor 6 may include a condensing lens.

The shape identifying unit 81 of the optical device control unit 8 acquires the digital value obtained for each light-receiving region of the 3D sensor 6 from the 3D sensor 6.

Then, the shape identifying unit 81 measures the three-dimensional shape of the measurement target by a calculating distance to the measurement target for each light-receiving region based on the acquired digital value. The shape identifying unit 81 identifies a three-dimensional image from the measured three-dimensional shape.

The authentication processing unit 91 of the system control unit 9 performs an authentication process related to use of the information processing device 1 when the three-dimensional image of the measurement target that is an identification result identified by the shape identifying unit 81 matches a three-dimensional image stored in advance in the ROM or the like. The authentication process related to the use of the information processing device 1 is, for example, a process of determining whether to permit the use of the information processing device 1, namely the own device. When the measurement target is a face, if a three-dimensional image of the face matches a three-dimensional image of a face stored in a storage member such as a ROM, the authentication processing unit 91 permits the use of the information processing device 1, including various applications provided by the information processing device 1.

The shape identifying unit 81 and the authentication processing unit 91 are constituted by a CPU that executes a program, for example. These functions may also be implemented by an integrated circuit such as an ASIC or an FPGA. Further, these functions may also be implemented by cooperation between a CPU that executes software such as a program and an integrated circuit.

Although the optical device 3, the optical device control unit 8, and the system control unit 9 are separately illustrated in FIG. 4, the system control unit 9 may include the optical device control unit 8. The optical device control unit 8 may be included in the optical device 3. Further, the optical device 3, the optical device control unit 8, and the system control unit 9 may be integrated.

(Overall Configuration of Optical Device 3)

Next, the optical device 3 will be described in detail.

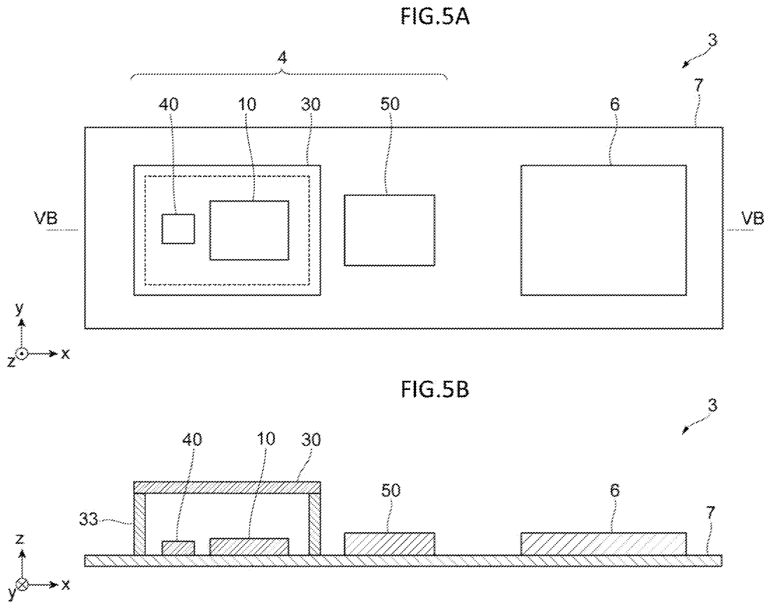

FIGS. 5A and 5B illustrate an example of a plan view and a cross-sectional view of the optical device 3 to which the present exemplary embodiment is applied. FIG. 5A is a plan view, and FIG. 5B is a cross-sectional view taken along line VB-VB of FIG. 5A. Here, in FIG. 5A, a lateral direction in FIG. 5A is defined as the x direction, an upper direction in FIG. 5A is defined as the y direction, and a front side direction perpendicular to a plane of FIG. 5A is defined as the z direction.

First, the plan view illustrated in FIG. 5A will be described.

In the optical device 3, the light-emitting device 4 and the 3D sensor 6 are arranged side by side in the x direction on a circuit board 7, for example. The circuit board 7 uses a plate-shaped member made of an insulating material as a base member, and the circuit board 7 is provided with a conductor pattern made of a conductive material. The insulating material is, for example, ceramic, epoxy resin, or the like. The conductive material is, for example, a metal such as copper (Cu) or silver (Ag), or a conductive paste containing such metals. The circuit board 7 may be a single-layer board having a conductor pattern provided on a front surface of the board, or may be a multi-layer board having plural layers of conductor patterns. The light-emitting device 4 and the 3D sensor 6 may be disposed on different circuit boards.

In the light-emitting device 4. the light-receiving element 40 for, monitoring light amount, the light source 10, and the driving unit 50 are arranged side by side in the x direction on the circuit board 7, for example. The diffusion plate 30 is provided to cover the light source 10 and the light-receiving element 40 for monitoring light amount.

A planar shape of the light source 10 is, for example, rectangular. It should be noted that the planar shape of the light source 10 may not be rectangular. A light-emitting direction (light-emitting side) of the light source 10 is the z direction. The light source 10 may be directly mounted on the circuit board 7, or may be mounted on the circuit board 7 via a heat dissipation base material such as aluminum oxide or aluminum nitride. When the heat dissipation base material is interposed between the light source 10 and the circuit board 7, electric power supplied to the light source 10 may be increased, and thus light output of the light source 10 may be increased. Hereinafter, the light source 10 will be described as being mounted directly on the circuit board 7. Here, the planar shape refers to a shape in a planar view, and the planar view refers to a view from the z direction in FIG. 5A. The same applies hereinafter. Here, the light output refers to a light flux.

The diffusion plate 30 is, for example, a member having a rectangular planar shape. The diffusion plate 30 diffuses and emits light incident on the diffusion plate 30. At this time, the diffusion plate 30 changes directivity of the light incident on the diffusion plate 30 and emits the light. That is, the diffusion plate 30 emits the light so as to provide a light intensity distribution different from a light intensity distribution in a ease where the light emitted from the light source 10 is emitted to the irradiated surface 310 without passing through the diffusion plate 30. For example, since the light source 10 has a small size as described later, the light source 10 may be regarded as a point light source. The diffusion plate 30 changes an irradiation pattern of the light incident from the light source 10 to the irradiation pattern on the irradiated surface 310 as illustrated in FIG. 3A.

A size of the diffusion plate 30 may be set such that, for example, a lateral width and a vertical width are 1 mm to 10 mm, and a thickness is 0.1 mm to 1 mm. The diffusion plate 30 may cover the light source 10 and the light-receiving element 40 for monitoring light amount in a plan view. Although an example in which the diffusion plate 30 has the rectangular shape in the plan view is described in FIG. 5A, the diffusion plate 30 may have another shape such as a polygonal shape or a circular shape. When the diffusion plate 30 has the size and the shape as described above, the diffusion plate 30 suitable for face authentication of the portable information processing terminal and three-dimensional shape measurement at a relatively short distance of about several meters is provided.

Next, the cross-sectional view illustrated in FIG. 5B will be described.

The diffusion plate 30 is supported by a side wall 33 on the z direction side, which is the light-emitting side of the light source 10. The side wall 33 is provided to surround the light source 10 and the light-receiving element 40 for monitoring light amount. The diffusion plate 30 is held by the side wall 33 at a predetermined distance from the light source 10 and the light-receiving element 40 for monitoring light amount. Then, the light incident on the diffusion plate 30 from the light source 10 is emitted from the diffusion plate 30 onto the irradiated surface 310 (see FIG. 2).

When the side wall 33 is formed of a member that absorbs the light emitted from the light source 10, the light emitted from the light source 10 is prevented from passing through the side wall 33 and being radiated to outside. In addition, since the light source 10 and the light-receiving element 40 for monitoring light amount are sealed by the diffusion plate 30 and the side wall 33, dust prevention, moisture prevention, and the like are achieved. In the present exemplary embodiment, b arranging the light source 10 and the light-receiving element 40 for monitoring light amount close to each other, the light source 10 and the light-receiving element 40 for monitoring light amount may be easily surrounded by the side wall 33 that has a small size, and thus the diffusion plate 30 is sufficient with a small size.

The light-receiving element 40 for monitoring light amount is a device that outputs an electric signal corresponding to an amount of received light (hereinafter, referred to as the received light amount). The light-receiving element 40 for monitoring light amount is, for example, a photodiode (PD) made of silicon or the like. The light-receiving element 40 for monitoring light amount is configured to receive light that is emitted from the light source 10 and reflected by a back surface of the diffusion plate 30, that is, a surface on the -z direction side of the diffusion plate 30.

The light source 10 is controlled based on the received light amount of the light-receiving element 40 fir monitoring light amount so as to maintain predetermined light output. That is, the optical device control unit 8 controls the light source 10 via the driving unit 50 based on the received light amount of the light-receiving element 40 for monitoring light amount. When the received light amount of the light-receiving element 40 for monitoring, light amount is extremely low, the diffusion plate 30 may be detached or damaged, and the light emitted from the light source 10 may be directly emitted to the outside without being diffused by the diffusion plate 30. In such a case, the optical device control unit 8 reduces the light output of the light source 10 via the driving unit 50. For example, the optical device control unit 8 stops emission of the light from the light source 10.

(Configuration of Light Source 10)

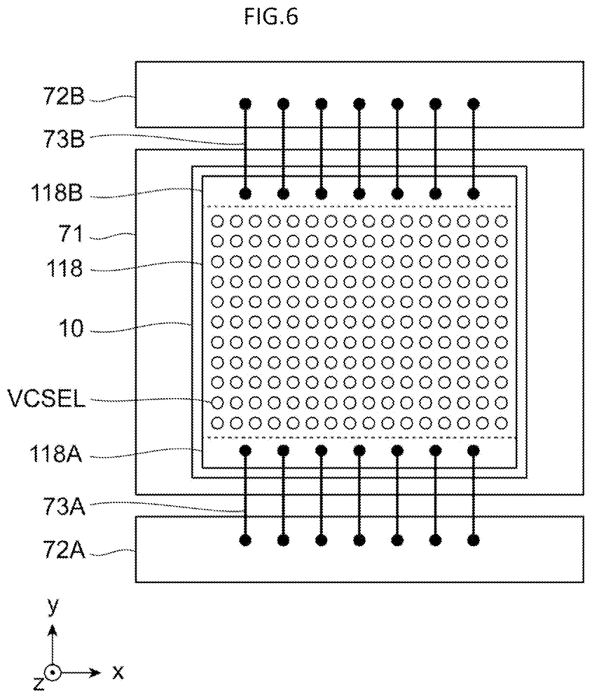

FIG. 6 illustrates an example of a plan, view of the light source 10. Here, a cathode pattern 71, anode patterns 72A and 72B, which are conductor patterns provided on the circuit board 7, and bonding wires 73A and 73B that connect the light source 10 and these conductor patterns are collectively illustrated.

In the present exemplary embodiment, the light source 10 includes a vertical-cavity surface-emitting laser (VCSEL) element. Hereinafter, the vertical-cavity surface-emitting laser element VCSEL is referred to as the VCSEL. The VCSEL is an example of a light-emitting element. As will be described later, in the VCSEL, an active region serving as a light-emitting region is provided between a lower multi-layer film reflector and an upper multi-layer film reflector that are stacked on a board, and a laser beam is emitted in a direction perpendicular to the board. Therefore, it is easy to form an array in which plural VCSELs are two-dimensionally arranged. The light source 10 is configured by integrating plural VCSELs as one semiconductor component.

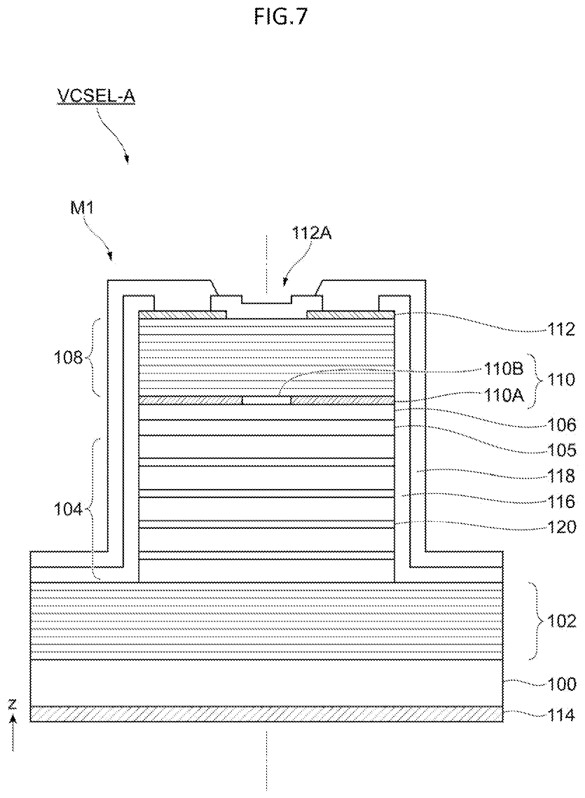

A cathode electrode 114 is provided on a back surface (see FIG. 7 to be described later), and an anode electrode 118 is provided on a front surface of the light source 10 including the plural VCSELs. The anode electrode 118 includes a portion connecting p-side electrodes 112 of the plural VCSELs a pad portion 118A to which the bonding wire 73A to be described later is connected, and a pad portion 118B to which the bonding wire 73B is connected. That is, the plural VCSELs are connected in parallel.

In FIG. 6, the plural VCSELs included in the light source 10 are arranged at each lattice point of a lattice formed in a square shape, for example. The plural VCSELs may be arranged in another array such as an array in which positions where the VCSELs are arranged for each row are shifted by a half of a repeating unit.

The cathode pattern 71 and the anode patterns 72A and 72B are provided as conductor patterns on the circuit board 7. The cathode pattern 71 is formed to have a larger area than the light source 10 such that the cathode electrode 114 provided on the back surface of the light source 10 is connected thereto. The cathode electrode 114 provided on the back surface of the light source 10 is bonded to the cathode pattern 71 on the circuit board 7 using a conductive adhesive. The pad portion 118A of the anode electrode 118 of the light source 10 is connected to the anode pattern 72A on the circuit board 7 by the bonding wire 73A, and the pad portion 118B of the anode electrode 118 of the light source 10 is connected to the anode pattern 72B on the circuit board 7 by the bonding wire 73B.

The number of VCSELs included in the light source 10 is, for example, 10 to 1000. The plural VCSELs are connected in parallel and driven in parallel. That is, the plural VCSELs simultaneously emit light. The light source 10 has a size of, for example, 0.5 mm square to 3 mm square. When irradiating a farther object to be irradiated, the number of VCSELs may be further increased.

As described above, the light source 10 emits the light in order to measure the three-dimensional shape of the measurement target. During the above-described user authentication based on the shape of the face, a measurement distance is about 10 cm to about 1 m. Thus, a length of one side of the detection range I is about 1 m. Since the light source 10 is required to irradiate the detection range I with light having predetermined light intensity, the VCSELs included in the light source 10 are required to have large light output.

In the present exemplary embodiment, a VCSEL that oscillates in a single transverse mode is used as each VCSEL included in the light source 10. The single transverse mode may be referred to as a single mode. Hereinafter, the VCSEL that oscillates in the single transverse mode is referred to as the single-mode VCSEL. Emitted light of the single-mode VCSEL has a smaller spread angle as compared with a VCSEL that oscillates in a multiple transverse mode. The multiple transverse mode may be referred to as a multi-mode. Therefore, the VCSEL that oscillates in the multiple transverse mode is referred to as a multi-mode VCSEL. The single transverse mode refers to a mode in which a light intensity profile of emitted light whose spread angle serves as a parameter has a unimodal characteristic, that is, a characteristic of having one light intensity peak. For example, plural transverse modes may be included within a range in which the unimodal characteristic is maintained. The spread angle of the emitted light refers to an angle range in which the light intensity is 1/e² of a maximum value. In addition, the spread angle may be an angle range that is a full width at half maximum (FWHM) of the light intensity.

As the single-mode VCSEL, a VCSEL having a long resonator structure may be used.

In the VCSEL having the long resonator structure, a spacer layer of several λ to several tens of λ is introduced between an active region in a VCSEL having a general λ resonator structure whose resonator length is an oscillation wavelength λ and one multi-layer reflector so as to increase the resonator length and thus increase a loss in a high-order transverse mode. Accordingly, single mode oscillation may be performed with an oxidation aperture diameter larger than an oxidation aperture diameter of the VCSEL having the general λ resonator structure. In a VCSEL having a typical λ resonator structure, since a longitudinal mode interval (may be referred to as a free spectrum range) is large, a stable operation may be obtained by a single longitudinal mode. On the other hand, in the case of the VCSEL having the long resonator structure, a longitudinal mode interval is narrowed since the resonator length is increased, and standing waves, namely plural longitudinal modes, are present in a resonator, and as a result, switching between the longitudinal modes is likely to occur. Therefore, in the VCSEL having the long resonator structure, a layer that prevents the switching between the longitudinal modes (a layer 120 causing optical loss in FIG. 7 to be described later) is provided.

In the single-mode VCSEL having the λ resonator structure, since the oxidation aperture diameter is set to be smaller than that of the multi-mode VCSEL having the λ resonator structure, it is difficult to increase the light output. Therefore, as the light source 10 that measures the three-dimensional shape, a multi-mode VCSEL haying large light output is used. However, in order to reduce spread light in the skirt range II and thus increase the light use efficiency, a single-mode VCSEL having a small spread angle may be used as described later. In addition, since the VCSEL having the long resonator structure is more likely to have a large oxidation aperture diameter as compared with the single-mode VCSEL having the general λ resonator structure, light output is more easily increased. The VCSEL having the long resonator structure is more likely to have a narrower spread angle as compared with the general single-mode VCSEL having the λ resonator structure.

(Single Mode VCSEL (VCSEL-A) having Long Resonator Structure)

FIG. 7 illustrates a cross-sectional structure of a single-mode VCSEL having a single long resonator structure included in the light source 10. Hereinafter, the single-mode VCSEL having the long resonator structure is referred to as VCSEL-A. An upper direction in FIG. 7 is the z direction.

The VCSEL-A is formed by stacking, on an n-type GaAs board 100: an n-type lower distributed Bragg reflector (hereinafter a distributed Bragg reflector is referred to as a DBR) 102 in which AlGaAs layers having different Al compositions are alternately stacked; a resonator extended region 104 formed on the lower DBR 102 to extend a resonator length; an n-type carrier block layer 105 formed on the resonator extended region 104; an active region 106 that is formed on the carrier block layer 105 and includes a quantum well layer interposed between an upper spacer layer and a lower spacer layer; and a p-type upper DBR 108 that is formed on the active region 106 and in which AlGaAs layers having different Al compositions are alternately stacked.

The n-type lower DBR 102 is a multi-layer laminate of pairs of an Al_{0.9}Ga_{0.1}As layer and a GaAs layer. A thickness of each layer is λ/4nᵣ (λ is the oscillation wavelength, and nᵣ is a refractive index of a medium). These layers are alternately stacked in 40 cycles. A carrier concentration after doping with silicon, which is an n-type impurity, is, for example, 3×10¹⁸ cm⁻³.

The resonator extended region 104 is a monolithic layer formed by a series of epitaxial growth. Therefore, the resonator extended region 104 is made of AlGaAs, GaAs, or AlAs whose lattice constant coincides or matches that of a GaAs board. Here, the resonator extended region 104 is made of AlGaAs that does not cause light absorption so as to emit laser beam in a 940 nm band. A film thickness of the resonator extended region 104 is set to 2 μm to 5 μm, and is set to 5λ to 20λ relative to the oscillation wavelength λ. Therefore, a movement distance of a carrier is increased. Therefore, the resonator extended region 104 may be an n-type region having a high carrier mobility, and thus the resonator extended region 104 is inserted between the n-type lower DBR 102 and the active region 106. Such a resonator extended region 104 may be referred to as a cavity extended region or a cavity space.

The carrier block layer 105 that has a large band gap and is made of, for example, Al_{0.9}Ga_{0.1}As may be formed between the resonator extended region 104 and the active region 106. Carrier leakage from the active region 106 is prevented and light emission efficiency is improved by inserting the carrier block layer 105. As will be described later, since the layer 120 causing optical loss, in which oscillation intensity of a laser beam is slightly attenuated, is inserted into the resonator extended region 104, the carrier block layer 105 plays a role of compensating for such loss. For example, a film thickness of the carrier block layer 105 is λ/4 mnᵣ (λ is the oscillation wavelength, m is an integer, and n^{r} is the refractive index of the medium).

The active region 106 is configured by stacking the lower spacer layer, the quantum well active layer, and the upper spacer layer. For example, the lower spacer layer is an undoped Al_{0.6}Ga_{0.4}As layer, the quantum well active layer is an undoped InGaAs quantum well layer and an undoped GaAs barrier layer, and the upper spacer layer is an undoped Al_{0.6}Ga_{0.4}As layer.

The p-type upper DBR 108 is a laminate of a p-type Al_{0.9}Ga_{0.1}As layer and a GaAs layer, a thickness of each layer is λ/4nᵣ, and these layers are alternately stacked in 29 cycles. A carrier concentration after doping with carbon, which is a p-type impurity is, for example, 3 ×10 cm⁻³. A contact layer made of p-type GaAs may be formed on an uppermost layer of the upper DBR 108. A p-type AlAs current confinement layer 110 is formed on a lowermost layer of the upper DBR 108 or in the upper DBR 108.

A cylindrical mesa M1 is formed on the board 100 by etching stacked semiconductor layers from the upper DBR 108 to the lower DBR 102. The current confinement layer 110 is exposed on a side surface of the mesa M1. An oxidized region 110A selectively oxidized from the side surface of the mesa M1 and a conductive region 110B surrounded by the oxidized region 110A are formed in the current confinement layer 110. The conductive region 110B is an oxide aperture. In an oxidation process, an AlAs layer has a higher oxidation rate than an AlGaAs layer, and the oxidized region 110A is oxidized from the side surface toward an inner side of the mesa M1 at a substantially constant rate, so that a planar shape of the conductive region 110B parallel to the board is a shape that reflects an outer shape of the mesa M1, that is, a circular shape, and a center of the shape coincides with an axial direction of the mesa M1 indicated by a dashed-dotted line. In the VCSEL having the long resonator structure, a diameter of the conductive region 110B for obtaining a single transverse mode may be easily made larger than that of the VCSEL having the general λ resonator structure, and for example, the diameter of the conductive region 110B may be increased to 7 μm to 8 μm. The semiconductor layers from the upper DBR 108 to the lower DBR 102 are stacked by epitaxy. Therefore, these semiconductor layers may be referred to as an epitaxial layer.

The annular p-side electrodes 112 each made of a metal in which Ti, Au, and the like are stacked are formed on an uppermost layer of the mesa M1. Each p-side electrode 112 is in ohmic contact with the contact layer of the upper DBR 108. An inner side of the annular p-side electrode 112 serves as a light emission port 112A through which a laser beam is emitted to the outside. That is, an axial direction of the mesa M1 is an optical axis. A front surface of the upper DBR 108 including the light emission port 112A is an emission surface. Further, the cathode electrode 114 that serves as an n-side electrode is formed on a back surface of the board 100.

An insulating layer 116 is provided in such a manner that a front surface of the mesa M1 is covered except for a portion where the p-side electrode 112 and the anode electrode 118 to be described later are connected and the light emission port 112A. The anode electrode 118 is provided to be in ohmic contact with the p-side electrode 112 except for the light emission port 112A. The anode electrode 118 is provided at a position except for a position where the light emission port 112A is provided on each of plural VCSEL-As. That is, in the plural VCSEL-As included in the light source 10, the respective p-side electrodes 112 are connected in parallel by the anode electrode 118 (see FIG. 6). As described above, the anode electrode 118 is provided as a continuous electrode pattern covering a region between each VCSEL-A except for the light emission port 112A of each VCSEL-A. Therefore, a pattern having a larger area is formed as compared with a case where drive wiring is individually provided for each VCSEL-A, and a voltage drop is prevented when a drive current flows.

In the VCSEL having the long resonator structure, since plural longitudinal modes may be present in a reflection band defined by the resonator length, it is required to prevent switching or hopping between the longitudinal modes. Here, an oscillation wavelength band of a required longitudinal mode is set to 940 nm, and the layer 120 causing optical loss for standing waves of an unnecessary longitudinal mode is provided in the resonator extended region 104 so as to prevent switching to an oscillation wavelength band of a longitudinal mode other than the required longitudinal mode. That is, the layer 120 causing optical loss is introduced at a position of a node of standing waves of the required longitudinal mode. The layer 120 causing optical loss is made of a semiconductor material having the same Al composition as a semiconductor layer constituting the resonator extended region 104, and is made of Al_{0.3}Ga_{0.7}As, for example. The layer 120 causing optical loss may have a higher impurity doping concentration than the semiconductor layer constituting the resonator extended region 104. For example, when an impurity concentration of AlGaAs constituting the resonator extended region 104 is 1×10¹⁷ cm⁻³, the layer 120 causing optical loss has an impurity concentration of 1×10¹⁸ cm⁻³, and is configured such that the impurity concentration is higher by about one order of magnitude than that of other semiconductor layers. When the impurity concentration is increased, absorption of light by a carrier is increased, which causes loss. A film thickness of the layer 120 causing optical loss is selected in such a manner that loss to the required longitudinal mode is not increased, and the layer 120 causing optical loss may have a film thickness substantially the same as a film thickness (10 nm to 30 nm) of the current confinement layer 110 located at the node of the standing waves.

The layer 120 causing optical loss is inserted so as to be located at the node relative to the standing waves in the required longitudinal mode. Since the standing waves has low light intensity at the node, an influence of loss caused by the layer 120 causing optical loss on the required longitudinal mode is reduced. On the other hand, for standing waves in an unnecessary longitudinal mode, the layer 120 causing optical loss is located at an antinode other than a node. Since the standing waves at the antinode has higher intensity than that at the node, loss to the unnecessary longitudinal mode caused by the layer 120 causing optical loss is increased. In this manner, since the loss to the required longitudinal mode is reduced while the loss to the unnecessary longitudinal mode is increased, the unnecessary longitudinal mode is selectively prevented from resonating, and thus hopping between longitudinal modes is prevented.

The layer 120 causing optical loss does not necessarily need to be provided at the position of the node of the standing waves of the required longitudinal mode in the resonator extended region 104, and may be a single layer. In this case, since intensity of standing waves increases as approaching the active region 106, the layer 120 causing optical loss may be formed at a position of a node close to the active region 106. If switching or hopping between longitudinal modes is allowed, the layer 120 causing optical loss may not be provided.

(Multiple Transverse Mode VCSEL having Resonator Structure (VCSEL-B))

Next, a multi-mode VCSEL having a λ resonator structure included in a light source 10′ illustrated for comparison will be described. The light source 10′ illustrated for comparison is illustrated in order to explain an influence of the spread angle of the emitted light of the VCSEL on the skirt spread. In the light-emitting device 4 for comparison, the light source 10 illustrated in FIGS. 5A and 5B is replaced with the light source 10′ described later. As described above, the emitted light of the multi-mode VCSEL having the λ resonator structure has a larger spread angle as compared with the single-mode VCSEL having the long resonator structure.

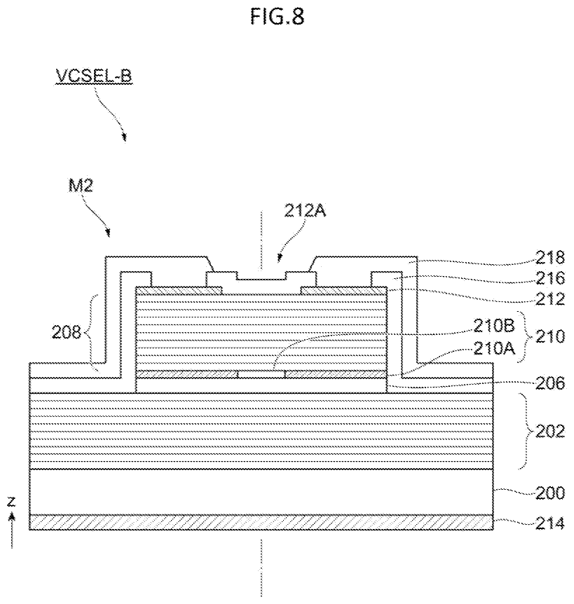

FIG. 8 illustrates a cross-sectional structure of a multi-mode VCSEL having a single λ resonator structure included in the light source 10′ for comparison. Hereinafter, the multi-mode VCSEL, having the A. resonator structure is referred to as VCSEL-B. The VCSEL-B does not include the resonator extended region 104 of the VCSEL-A. An upper direction in FIG. 8 is the z direction.

The VCSEL-B is formed by stacking, on an n-type GaAs board 200: an n-type lower DBR 202 in which AlGaAs layers having different Al compositions are alternately stacked; an active region 206 that is formed on the lower DBR 202 and includes a quantum well layer interposed between an upper spacer layer and a lower spacer layer; and a p-type upper DBR 208 that is formed on the active region 206 and in which AlGaAs layers having different Al compositions are alternately stacked. A p-type AlAs current confinement layer 210 is formed on a lowermost layer of the upper DBR 208 or in the upper DBR 208.

Since the lower DBR 202, the active region 206, the upper DBR 208, and the current confinement layer 210 are the same as the lower DBR 102, the active region 106, the upper DBR 108, and the current confinement layer 110 of the VCSEL-A described above, description thereof will be omitted.

Stacked semiconductor layers from the upper DBR 208 to the lower DBR 202 are etched in such a manner that a cylindrical mesa M2 is formed on the board 200, and the current confinement layer 21 is exposed on a side surface of the mesa M2. An oxidized region 210A selectively oxidized from the side surface of the mesa M2 and a conductive region 210B surrounded by the oxidized region 210A are formed in the current confinement layer 210. The conductive region 210B is an oxide aperture. A planar shape of the conductive region 210B parallel to the board is a shape that reflects an outer shape of the mesa M2, that is, a circular shape, and a center of the shape substantially coincides with an axial direction of the mesa M2 indicated by a dashed-dotted line.

An annular p-side electrode 212 made of a metal in which Ti, Au and the like are stacked is formed on an uppermost layer of the mesa M2, and the p-side electrode 212 is in ohmic contact with a contact layer of the upper DBR 208. A circular light emission port 212A whose center coincides with the axial direction of the mesa M2 is formed in the p-side electrode 212, and a laser beam is emitted to the outside from the light emission port 212A. That is, the axial direction of the mesa M2 is an optical axis. Further, a cathode electrode 214 is formed as an n-side electrode on a back surface of the board 200. A front surface of the upper DBR 208 including the light emission port 212A is an emission surface.

An insulating layer 216 is provided in such a manner that a front surface of the mesa M2 is covered except for a portion where the p-side electrode 212 and an anode electrode 218 to be described later are connected and the light emission port 212A. The anode electrode 218 is provided to be in ohmic contact with the p-side electrode 212 except for the light emission port 212A. The anode electrode 218 is provided at a position except for a position where the light emission port 212A of each of plural VCSEL-Bs is located. That is, in the plural VCSEL-Bs included in the light source 10′, the respective p-side electrodes 212 are connected in parallel by the anode electrode 218.

Next, a relationship between the spread angle of the light emitted from the VCSEL of the light source 10 and the skirt spread will be described.

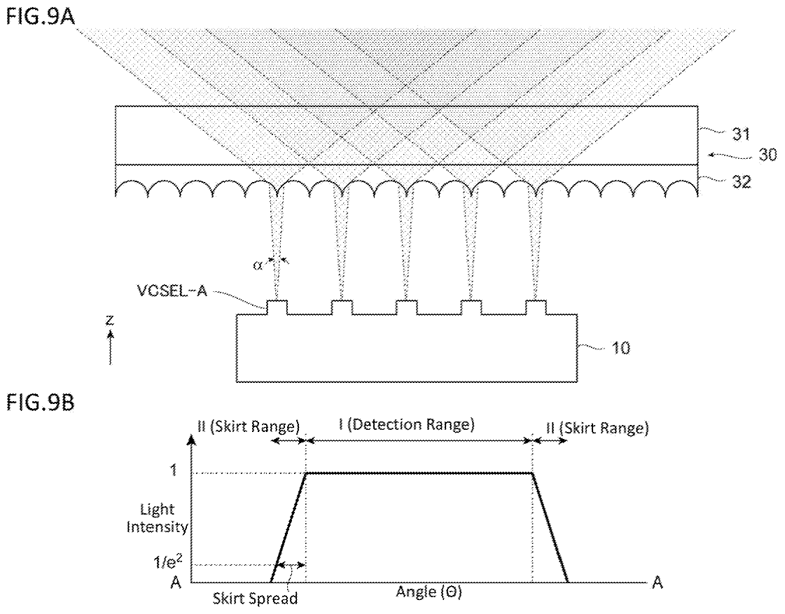

FIGS. 9A and 9B schematically illustrate a relationship between a spread angle of light emitted from the single-mode VCSEL having the long resonator structure (VCSEL-A) and a skirt spread in a light intensity distribution. FIG. 9A illustrates a spread angle α of the light emitted from the single-mode VCSEL (VCSEL-A), and FIG. 9B illustrates the light intensity distribution. An upper direction in FIG. 9A is the z direction. The light intensity distribution illustrated in FIG. 9B is the light intensity distribution along line A-A illustrated in FIG. 3A.

As illustrated in FIG. 9A, the light emitted from the VCSEL-A of the light source 10 is emitted at the spread angle α. The spread angle is a full width at half maximum (FWHM) or 1/e² of the light intensity.

Here, the diffusion plate 30 will be further described with reference to FIG. 9A. The diffusion plate 30 includes, for example, a flat glass base material 31 whose two surfaces are parallel to each other, and a resin layer 32 in which plural minute concave and convex portions for diffusing light are formed on a front surface on one side of the glass base material. The diffusion plate 30 is provided on a path (referred to as a light-emitting path) of the light emitted from the VCSEL-A of the light source 10, and diffuses and emits incident light by the concave and convex portions of the resin layer 32. At least one of the plural convex portions and the plural concave portions constituting the concave and convex portions of the resin layer 32 has, for example, a width of 10 μm or more and 100 μm or less and a height (depth) of 1 μm or more and 50 μm or less. In addition, the concave and convex portions may have a pattern having a pitch, or may have a random pattern having no pitch. A refraction direction of the light is controlled by the pattern of the concave and convex portions on the diffusion plate 30, and thus the light emitted from the light source 10 is changed to a desired irradiation pattern. The pattern of the concave and convex portions may be referred to as a lens pattern.

The diffusion plate 30 may be configured to have uniform diffusion angle over the entire diffusion plate 30, or may be configured to have different diffusion angles depending on a position thereof The diffusion plate 30 may be configured such that an optical axis of the VCSEL-A coincides with and a central axis of the light emitted front the diffusion plate 30, or may be configured such that the central axis of the light emitted from the diffusion plate 30 is intentionally shifted relative to the optical axis of the VCSEL-A to increase an irradiation area. The diffusion angle refers to a spread angle of emitted light when parallel light is incident.

As illustrated in FIG. 9A, the diffusion plate 30 diffuses the light having the spread angle apt. emitted from the VCSEL-A and emits the light to the irradiated surface 310 (see FIG. 2). At this time, the diffusion plate 30 superimposes the light emitted from each VCSEL-A and emit the light.

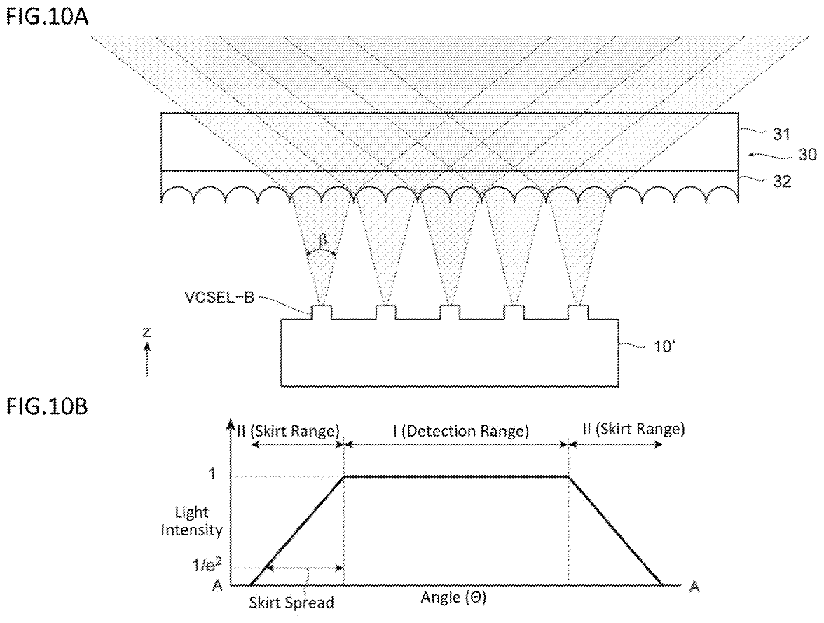

FIGS. 10A and 10B schematically illustrate a relationship between a spread angle β of light emitted from the multi-mode VCSEL having the λ resonator structure (VCSEL-B) and a skirt spread in a light intensity distribution for comparison. FIG. 10A illustrates the spread angle β of the light emitted from the multi-mode VCSEL(VCSEL-B), and FIG. 10B illustrates the light intensity distribution. An upper direction in FIG. 10A is the z direction. The light intensity distribution illustrated in FIG. 10B is the light intensity distribution along line A-A illustrated in 3A. Here, the diffusion plate 30 is the same as in the case of the single-mode VCSEL (VCSEL-A) having the long resonator structure illustrated in FIG. 9A.

As illustrated in FIG. 10A, the VCSEL-B emits light at the spread angle β that is larger than the spread angle of the emitted light of the VCSEL-A (α<β). In this case, a skirt spread in the case of using the light source 10′ including the VCSEL-B (spread angle β) illustrated in FIG. 10B is larger than a skirt spread in the case of using the light source 10 including the VCSEL-A (spread angle α) illustrated in FIG. 9B. This is because light with various incident angles is incident on the diffusion plate 30 when the spread angle of the light emitted from the light source is large as compared with a case where the spread angle is small, and thus a range of an angle of refraction is widened due to the lens pattern of the diffusion plate 30. That is, as the spread angle of the light emitted from the light source increases, the angle of refraction takes more various values. Then, it becomes difficult to change the irradiation pattern of the light irradiated from the diffusion plate 30 to the desired irradiation pattern, and when the irradiation pattern has a quadrangular shape, the quadrangular shape is blurred. That is, as the spread angle of the light emitted from the light source increases, the skirt spread increases.

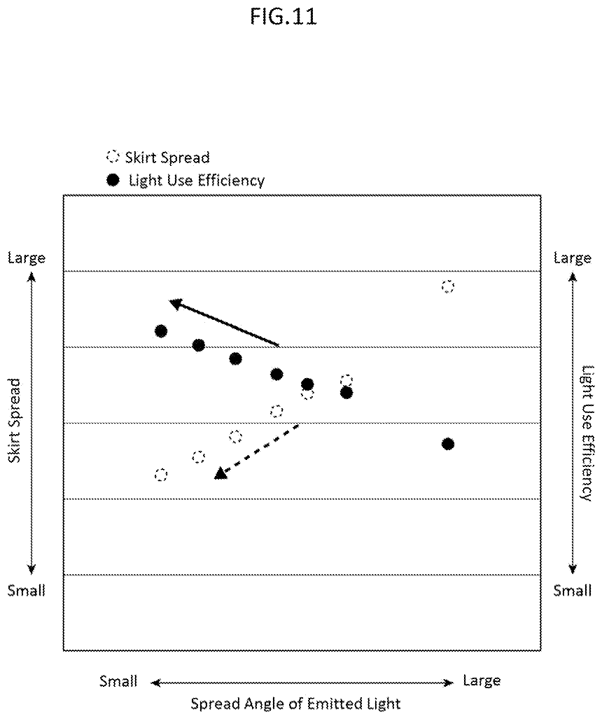

FIG. 11 illustrates a relationship between the spread angle of the light emitted from the VCSEL, the skirt spread, and the light use efficiency. A horizontal axis represents the spread angle of the emitted light, a vertical axis on a left side represents the skirt spread, and a vertical axis on a right side represents the light use efficiency. These relationships are obtained by simulation.

As illustrated in FIG. 11, as the spread angle of the emitted light decreases, the skirt spread on the irradiated surface 310 may decrease, and the light use efficiency is improved.

Here, since the spread angle of the emitted light and the skirt spread on the irradiated surface 310 are related to each other, during the three-dimensional shape measurement by the TOF method in which the light source 10 is required to have large light output, the single-mode VCSEL whose emitted light has a small spread angle is used instead of adopting the multi-mode VCSEL having the λ resonator structure with which large light output is intentionally achieved. As a result, the skirt range II in which light is irradiated outside the predetermined range on the irradiated surface 310 is narrowed. In this way, the light use efficiency is improved by reducing a skirt portion of the light, that is, by reducing the skin spread. In this way, power consumption of the light source is reduced as compared with a case where the skirt spread is not reduced. In particular, a long driving time is achieved in an information processing device driven by a battery, such as a portable information processing device.

Although an example in which the plural VCSELs are connected in parallel is described in the above exemplary embodiment, a configuration in which plural VCSELs are connected in series or a connection configuration in which series connection and parallel connection are combined may be used.

Although an example in which the plural VCSELs are configured in a mesa shape is described in the above exemplary embodiment, the plural VCSELs may be configured in a form other than the mesa shape. For example, plural holes may be provided to surround the emission port of each VCSEL, and the current confinement layer 110 may be oxidized using the holes so as to form a VCSEL having an oxidized confinement structure.

Although the plural VCSELs emit light from the surface side (front surface side) on which the epitaxial layer is formed on the board 100 in the above exemplary embodiment, light may be emitted from a surface side (back surface side) on which the epitaxial layer is not formed.

Although the light source 10 and the diffusion plate 30 are disposed at positions overlapping each other when viewed from the light emission surface side in the above exemplary embodiment, the light source 10 and the diffusion plate 30 may be disposed at positions not overlapping each other. For example, a configuration in which light may be diffused via a reflection member such as a reflection mirror even though the diffusion plate 30 and the light source 10 are disposed at positions not overlapping each other may be adopted.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A light-emitting device comprising:
a light source comprising a plurality of light-emitting elements configured to oscillate in a single transverse mode; and
an optical member that is provided on a light-emitting path of the light source and is configured to diffuse and emit light emitted by the light source.

2. The light-emitting device according to claim 1, wherein the light-emitting element is a vertical-cavity surface-emitting laser element.

3. The light-emitting device according to claim 2, wherein the vertical-cavity surface-emitting laser element has a long resonator structure.

4. The light-emitting device according to claim 1, further comprising an electrode pattern that connects the plurality of light-emitting elements in parallel to each other, the electrode pattern covering a region excluding emission ports of the light-emitting elements in a continuous pattern.

5. The light-emitting device according to claim 2, further comprising an electrode pattern that connects the plurality of light-emitting elements in parallel to each other, the electrode pattern covering a region excluding emission ports of the light-emitting elements in a continuous pattern.

6. The light-emitting device according to claim 3, further comprising an electrode pattern that connects the plurality of light-emitting elements in parallel to each other, the electrode pattern covering a region excluding emission ports of the light-emitting elements in a continuous pattern.

7. The light-emitting device according to claim 1, wherein the optical member is configured to emit the light emitted from the light source while changing directivity of the light.

8. The light-emitting device according to claim 2, wherein the optical member is configured to emit the light emitted from the light source while changing directivity of the light.

9. The light-emitting device according to claim 3, wherein the optical member is configured to emit the light emitted from the light source while changing directivity of the light.

10. The light-emitting device according to claim 4, wherein the optical member is configured to emit the light emitted from the light source while changing directivity of the light.

11. The light-emitting device according to claim 5, wherein the optical member is configured to emit the light emitted from the light source while changing directivity of the light.

12. The light-emitting device according to claim 6, wherein the optical member is configured to emit the light emitted from the light source while changing directivity of the light.

13. The light-emitting device according to claim 7, wherein the optical member is a plate-like member having a structure configured to change a directivity of light on at least one surface of the plate-like member.

14. The light-emitting device according to claim 8, wherein the optical member is a plate-like member having a structure configured to change a directivity of light on at least one surface of the plate-like member.

15. The light-emitting device according to claim 1, wherein the optical member is configured to emit light used for measuring a three-dimensional shape by a time-of-flight method.

16. The light-emitting device according to claim 1, wherein the light source and the optical member are mounted on a portable information processing terminal, and the light source is driven by a battery.

17. A light-emitting device comprising:
a light source comprising a plurality of vertical-cavity surface-emitting laser elements each having a long resonator structure; and
an optical member that is provided in a light-emitting path of the light source and configured to diffuse and emit light emitted by the light source.

18. An optical device comprising:
the light-emitting device according to claim 1; and
a light-receiving unit configured to receive light that is emitted from a light source of the light-emitting device and reflected by a measurement target,
wherein the light-receiving unit is configured to output a signal corresponding to a time from when the light is emitted from the light source to when the light is received by the light-receiving unit.

19. An information processing device comprising:
the optical device according to claim 18; and
a shape identifying unit configured to identify a three-dimensional shape of the measurement target based on the light that is emitted from the light source of the light-emitting device of the optical device, reflected by the measurement target, and received by the Light-receiving unit of the optical device.

20. An information processing device according to claim 19, further comprising
an authentication processing unit configured to perform an authentication process related to use of the information processing device based on a result of identification performed by the shape identifying unit.
